(19) United States
(12) Patent Application Publication
(10) Pub. No.: US 2023/0411367 A1
(43) Pub. Date: Dec. 21, 2023

(54) DISCHARGE CIRCUIT MODULE

(71) Applicant: Rohm Co., Ltd., Kyoto (JP)

(72) Inventor: Ippei YASUTAKE, Kyoto (JP)

(21) Appl. No.: 18/034,957

(22) PCT Filed: Oct. 26, 2021
(86) PCT No.: PCT/JP2021/039425

§ 371 Date: May 2, 2023

(30) Foreign Application Priority Data
Nov. 9, 2020 (JP) 2020-186408

(51) Int. Cl. H01L 25/16; H01L 23/373

(52) U.S. Cl. CPC H01L 25/165; H01L 24/45; H01L 23/3735

(57) ABSTRACT

A discharge circuit module (1) is a discharge circuit module for discharging a capacitance portion (CX), and includes an insulative substrate (40), a discharge resistor portion (R) having at least one resistor (51, 52) formed on the insulative substrate, and a semiconductor chip (6) implemented on the insulative substrate as a semiconductor switch and electrically connected to the discharge resistor portion. The insulative substrate, the discharge resistor portion, and the semiconductor chip are formed into a package.

### TECHNICAL FIELD

The invention disclosed herein relates to a discharge circuit module.

### BACKGROUND ART

Conventionally, capacitors that are connected between supply lines are known as X capacitors. To protect the human body from an electric shock from electric charge charged in X capacitors, discharge circuits are often provided to discharge X capacitors.

Some such discharge circuits include a circuit in which a resistor and a switch are connected in series (for example, Patent Document 1). The series circuit is connected in parallel with an X capacitor. Turning on the switch permits the electric charge in the X capacitor to be discharged via the resistor.

### CITATION LIST

### Patent Literature

Patent Document 1: Japanese Unexamined Patent Application Publication No. 2013-158211 (FIG. 8)

### SUMMARY OF INVENTION

### Technical Problem

Inconveniently, conventional discharge circuits as mentioned above often employ ceramic resistors or chip resistors arrayed on a substrate, and this may lead to their having an increased size.

An object of the invention disclosed herein is to provide a discharge circuit module that can be made compact.

### Solution to Problem

For example, a discharge circuit module according to one aspect of what is disclosed herein is a discharge circuit module for discharging a capacitance portion, and includes an insulative substrate, a discharge resistor portion having at least one resistor formed on the insulative substrate, and a semiconductor chip implemented on the insulative substrate as a semiconductor switch and electrically connected to the discharge resistor portion. The insulative substrate, the discharge resistor portion, and the semiconductor chip are formed into a package.

### Advantageous Effects of Invention

According to what is disclosed herein, a discharge circuit module can be made compact.

### BRIEF DESCRIPTION OF DRAWINGS

FIG. 1 is a diagram showing a circuit configuration of a discharge system according to an illustrative embodiment of what is disclosed herein.

FIG. 2 is an exploded perspective view of a discharge circuit module.

FIG. 3 is a perspective view of the discharge circuit module in its assembled state.

FIG. 4 is a circuit diagram showing a configuration of a discharge circuit in the discharge circuit module.

FIG. 5 is a circuit diagram showing a configuration of the discharge circuit according to one modified example.

FIG. 6 is a circuit diagram showing a configuration of a discharge resistor portion according to one modified example.

FIG. 7 is a perspective view schematically showing a discharge circuit module according to one modified example.

### DESCRIPTION OF EMBODIMENTS

Hereinafter, an illustrative embodiment of what is disclosed herein will be described with reference to the drawings.

<1. Configuration of a Discharge System>

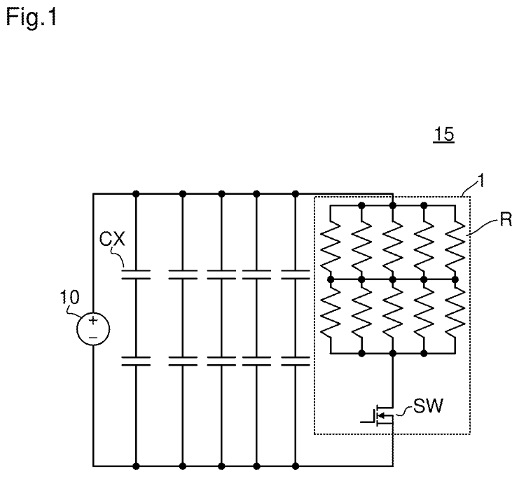

FIG. 1 is a diagram showing the circuit configuration of a discharge system 15 according to the illustrative embodiment of what is disclosed herein. The discharge system 15 shown in FIG. 1 includes a capacitance portion CX composed of a plurality of capacitors and a discharge circuit module 1.

The capacitance portion CX corresponds to an X capacitor connected between supply lines. In the configuration in FIG. 1, as one example, the capacitance portion CX is configured as a parallel circuit of five series circuits each composed of two capacitors connected between the positive and negative sides of a battery 10. This however is not meant as any limitation; instead, for example, the capacitance portion CX may be formed by one capacitor connected between the positive and negative sides of a battery 10.

The discharge circuit module 1, of which a configuration will be described later, is a discharge circuit formed into a package, and includes a discharge resistor portion R and a semiconductor switch SW. In the configuration in FIG. 1, as one example, the discharge resistor portion R is configured with a plurality of resistors. This however is not meant as any limitation; instead, the discharge resistor portion R may be configured with one resistor.

In the configuration in FIG. 1, as one example, the semiconductor switch SW is configured with a SiC-MOSFET (metal-oxide-semiconductor field-effect transistor) using SiC (silicon carbide) as a semiconductor material. This however is not meant as any limitation; instead, for example, the semiconductor switch SW may be configured with a Si-MOSFET or a Si-IGBT (insulated-gate bipolar transistor). In the configuration in FIG. 1, as one example, the semiconductor switch SW is an N-channel MOSFET.

One terminal of the discharge resistor portion R is connected to the positive side of the battery 10 (capacitance portion CX). The other terminal of the discharge resistor portion R is connected to the first terminal of the semiconductor switch SW. The second terminal of the semiconductor switch SW is connected to the negative side of the battery (capacitance portion CX). As shown in FIG. 1, in a case where the semiconductor switch SW is configured with an N-channel MOSFET, the first terminal corresponds to the drain and the second terminal corresponds to the source.

The semiconductor switch SW is turned on and off by a control voltage fed to the control terminal (gate) of the semiconductor switch SW. If the semiconductor switch SW is turned on with electric charge stored in the capacitor portion CX, a discharge current flows via the discharge resistor portion R and the semiconductor switch SW so that the electric charge stored in the capacitor portion CX is discharged.

In a case where the discharge system 15 is incorporated in, for example, an EV (electric vehicle), the DC voltage across the capacitor portion CX is as high a voltage as, for example, 600V to 900V. Thus, a high-withstand-voltage device with a withstand voltage of, for example, 1200V is used for the semiconductor switch SW. The resistance value of the discharge resistor portion R is determined to comply with the local safety standards, as by determining it based on the time constant that permits the voltage across the capacitor portion CX to fall to a predetermined voltage (for example, 45V) or less in a predetermined period of time (for example, 2 sec) after the start of discharge. The resistance value of the discharge resistor portion R is, for example, several tens of ohms.

In a case where, as described above, the voltage across the capacitor portion CX is a high voltage, a large amount of heat is generated by the power consumed in the discharge resistor portion R and the semiconductor switch SW. Configuring the discharge circuit module 1 as will be described later helps improve heat dissipation.

<2. Structure of a Discharge Circuit Module>

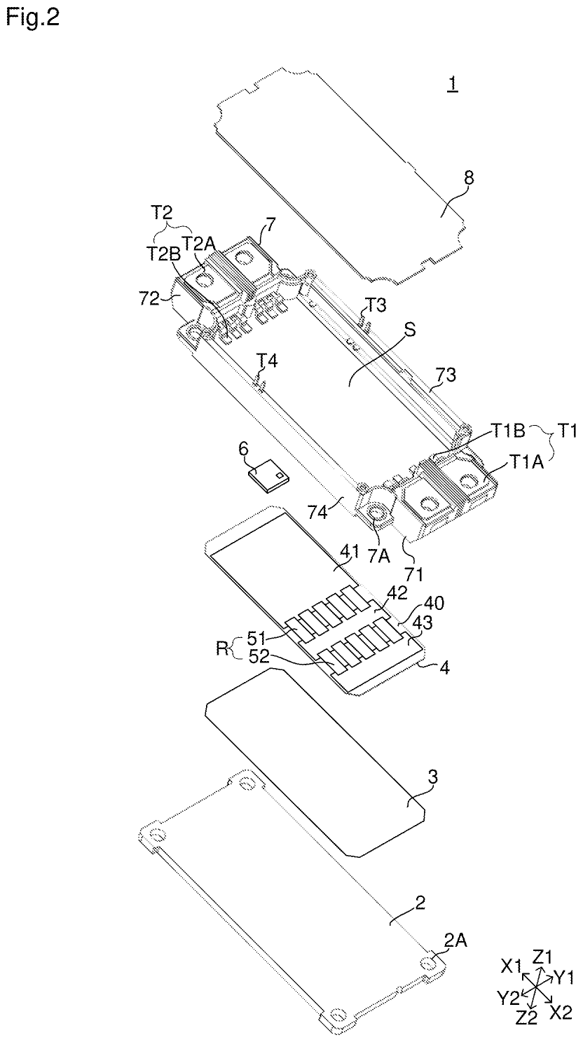

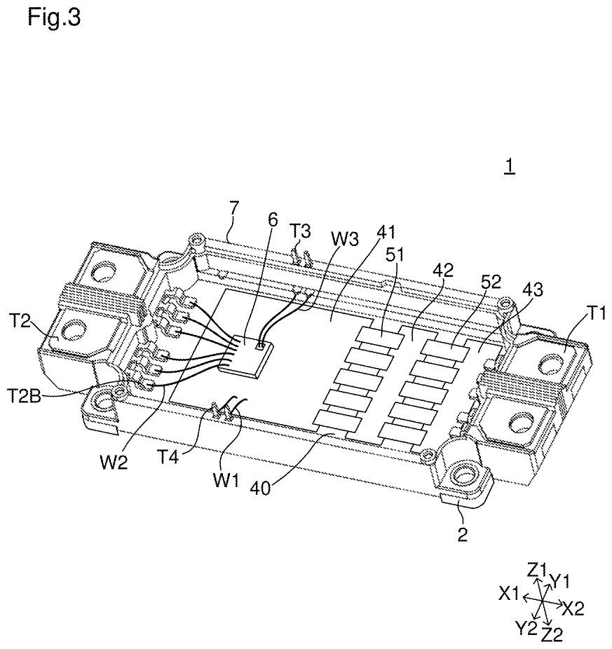

Next, the structure of the discharge circuit module 1 will be described in detail. FIG. 2 is an exploded perspective view of the discharge circuit module 1. FIG. 3 is a perspective view of the discharge circuit module 1 in its assembled state. In FIG. 3, a cover 8 is omitted from illustration for convenience′ sake.

In FIGS. 2 and 3, the longitudinal direction (first direction) is taken as the X direction, with one side of the longitudinal direction identified as X1 and the other side as X2. The lateral direction (second direction) is taken as the Y direction, with one side of the lateral direction identified as Y1 and the other side as Y2. The up-down direction is taken as the Z direction, with the upward direction identified as Z1 and the downward direction as Z2. The longitudinal direction, the lateral direction, and the up-down direction are orthogonal to each other.

As shown in FIGS. 2 and 3, the discharge circuit module 1 includes a copper plate 2, a solder portion 3, a DCB substrate 4, a first resistor group 51, a second resistor group 52, a semiconductor chip 6, a resin case 7, and a cover 8. The discharge circuit module 1 further include external terminals T1 to T4 for establishing electrical connection with the outside.

The copper plate 2 is a plate-form member made of copper that is substantially rectangular shape as seen from above, extending in the longitudinal and lateral directions, and that has its thickness direction aligned with the up-down direction. The copper plate 2 has good thermal conductivity. This however is not meant as any limitation: instead of the copper plate 2, a metal plate made of a metal other than copper with good thermal conductivity, such as aluminum, may be used.

The resin case 7 is a housing made of resin. Instead of the resin case 7, a housing made of an insulating material other than resin may be used. The resin case 7 integrally has a first mount base portion 71, a second mount base portion 72, a first side portion 73, and a second side portion 74.

The first and second side portions 73 and 74 are each a substantially wall-form member extending in the longitudinal direction. The first- and second-side portions 73 and 74 are disposed opposite each other in the lateral direction. The first mount base portion 71 is disposed at the other side in the longitudinal direction and the second mount base portion 72 is disposed at the one side in the longitudinal direction. The external terminal T1 is placed on the first mount base portion 71 and the external terminal T2 is placed on the second mount base portion 72. The first- and second-side portions 73 and 74 connect together the first and second mount base portions 71 and 72 in the longitudinal direction. Surrounded by the first and second mount base portions 71 and 72 and the first- and second-side portions 73 and 74, a storage portion S, which is a space open at the top and at the bottom, is formed inside the resin case 7.

In the four corners of the resin case 7 as seen from above, fastening holes 7A are formed that penetrate it in the up-down direction. In the four corners of the copper plate 2 as seen from above, through holes 2A are formed that penetrate it in the up-down direction. The copper plate 2 is disposed below the resin case 7 and, in this state, the penetration hole portion 2A and the fastening hole portion 7A overlap each other as seen from above to form one penetration hole in each corner. Through each pair of a through hole 2A and a fastening hole 7A, a bolt (not illustrated) is inserted in the up-down direction to fasten a heat sink (not illustrated) below the copper plate 2. The heat sink, for example, is a water-cooling heat sink.

The DCB (direct copper bonding) substrate 4 is a plate-form member extending in the longitudinal and lateral directions, and that has its thickness direction aligned with the up-down direction. The DCB substrate 4 has a ceramic substrate 40, a first wiring portion 41, a second wiring portion 42, and a third wiring portion 43. The DCB substrate 4 is formed by directly bonding the first, second, and third wiring portions 41, 42, and 43, which are copper plates, to the ceramic substrate 40.

The ceramic substrate 40 is formed of, for example, alumina, aluminum nitride, or silicon nitride and has good thermal conductivity. The ceramic substrate 40 is one example of an insulative substrate.

From one side to the other side in the longitudinal direction, the first, second, and third wiring portions 41, 42, and 43 are arranged in this order. The first, second, and third wiring portions 41, 42, and 43 extend in the lateral direction. The first resistor group 51 is formed by printing on the ceramic substrate 40 so as to connect together the first and second wiring portions 41 and 42. The first resistor group 51, as one example, is configured with five resistors extending in the longitudinal direction and arrayed in the lateral direction. Likewise, the second resistor group 52 is formed by printing on the ceramic substrate 40 so as to connect together the second and third wiring portions 42 and 43. The second resistor group 52, as one example, is configured with five resistors extending in the longitudinal direction and arrayed in the lateral direction.

Each resistor in the first and second resistor groups 51 and 52 is formed of, for example, a metal such as silver or silver/palladium (Ag/Pd), or a metallic oxide such as ruthenium oxide (RuO₂).

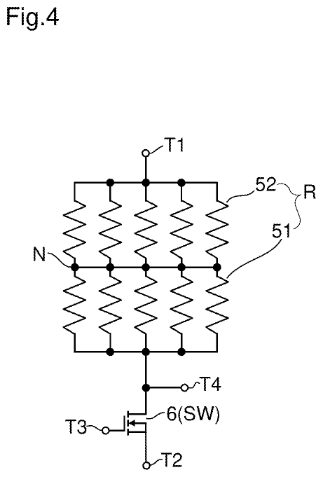

With the configuration described above, five series circuits each composed of one resistor in the first resistor group 51 and one resistor in the second resistor group 52 are connected in parallel to form a discharge resister portion R. FIG. 4 is a circuit diagram showing a configuration of the discharge circuit in the discharge circuit module 1. The discharge resistor portion R, as one example shown in FIG. 4, is configured with two series- and five parallel-connected resistors.

As shown in FIG. 4, the second wiring portion 42 short-circuits together the connection nodes N in the series circuits of resistors. Thus, even if one of the resistors in a series circuit of resistors is disconnected from the second wiring portion 42 for some reason, the other resistor remains connected to the second wiring portion 42, so it is possible to suppress a change in the resistance value of the discharge resistor portion R as a whole.

The DCB substrate 4 is disposed above the copper plate 2. The solder portion 3 is disposed by being sandwiched between the DCB substrate 4 and the copper plate 2 in the up-down direction. The DCB substrate 4 is bonded to the top face of the copper plate 2 via the solder portion 3. The DCB substrate 4 and the first and second resistor groups 51 and 52 are housed in the storage portion S.

The external terminal T1 integrally has a mount portion T1A and a leg portion T1B. The mount portion T1A is a plate-form part mounted on the first mount base portion 71. The leg portion T1B is connected to a part penetrating from the mount portion T1A through the first mount base portion 71 and is formed so as to project from a lower part of the first mount base portion 71 at one side in the longitudinal direction toward the storage portion S. The leg portion T1B is formed so as to extend from the first mount base portion 71 first in one direction in the longitudinal direction, then downward, and then again in one direction in the longitudinal direction.

The external terminal T1, as one example, is made of copper. The third wiring portion 43 formed on the ceramic substrate 40 as mentioned above is electrically connected to the external terminal T1 by making contact with the leg portion T1B from below. That is, the third wiring portion 43 is connected to the external terminal T1 by a Cu clip.

The semiconductor chip 6 corresponds to the semiconductor switch SW (see FIG. 4). The bottom face of the semiconductor chip 6 is bonded to the top face of the first wiring portion 41 via a solder portion which is not illustrated. The external terminal T4 has a part projecting upward from the top face of the second side portion 74. The top face of the first wiring portion 41 is connected to a lower end part of the external terminal T4 via a first bonding wire W1 (see FIG. 3). The first bonding wire W1 is formed of, for example, aluminum.

Thus, as shown in FIG. 4, in a case where the semiconductor chip 6 (semiconductor switch SW) is an N-channel MOSFET, the drain of the semiconductor chip 6 is electrically connected to the external terminal T4.

The external terminal T2 integrally has a mount portion T2A and a leg portion T2B. The mount portion T2A is a plate-form part mounted on the second mount base portion 72. The leg portion T2B is connected to a part penetrating from the mount portion T2A through the second mount base portion 72 and is formed so as to project from a lower part of the second mount base portion 72 at the other side in the longitudinal direction toward the storage portion S. The leg portion T2B is formed so as to extend from the second mount base portion 72 first in the other direction in the longitudinal direction, then downward, and then again in the other direction in the longitudinal direction.

The source pad of the semiconductor chip 6 is connected by the leg portion T2B and a second bonding wire W2 (see FIG. 3). The second bonding wire W2 is formed of, for example, aluminum. Thus, as shown in FIG. 4, the source of the semiconductor chip 6 is electrically connected to the external terminal T2.

The external terminal T3 has a part projecting upward from the top face of the first side portion 73. The gate pad of the semiconductor chip 6 is connected to a lower end part of the external terminal T3 by a third bonding wire W3 (see FIG. 3). The third bonding wire W3 is formed of, for example, aluminum. Thus, as shown in FIG. 4, the gate of the semiconductor chip 6 is electrically connected to the external terminal T3.

Note that bonding ribbons may be used instead of bonding wires W1 to W3.

A wiring (not illustrated) having an O ring is fastened on the mount portion T1A with a bolt (not illustrated), which is inserted through the through holes formed in the mount portion T1A of the external terminal T1 and the first mount base portion 71, and a nut (not illustrated), which is fastened to the bolt. Thus, the external terminal T1 is electrically connected to the positive side of the capacitance portion CX (see FIG. 1) by the wiring.

A wiring (not illustrated) having an O ring is fastened on the mount portion T2A with a bolt (not illustrated), which is inserted through the through holes formed in the mount portion T2A of the external terminal T2 and the second mount base portion 72, and a nut (not illustrated), which is fastened to the bolt. Thus, the external terminal T2 is electrically connected to the negative side of the capacitance portion CX by the wiring.

The cover 8 is attached to the resin case 7 so as to cover the storage portion S from above.

Thus, with the discharge circuit module 1 according to this embodiment, by packaging the resistors formed by printing on the DCB substrate 4 and the semiconductor switch as the semiconductor chip 6 implemented on the DCB substrate 4, it is possible to make the discharge circuit module 1 compact.

Even if the resistors and the semiconductor switch generate heat when the capacitance portion CX discharges, the generated heat is dissipated from the heat sink by conducting through the ceramic substrate 40 and the copper plate 2, which have good thermal conductivity, and this helps improve heat dissipation.

The ceramic substrate 40 has a large heat capacity, so even if the number of resistors is reduced, it is possible to suppress a transient rise in temperature. For example, conventionally, in order to achieve a resistance value of several tens of ohms comparable with that of the discharge resistor portion R, about 100 chip resistors need to be arranged on the substrate; by contrast, in this embodiment, only about 10 resistors are required.

<3. Modifications>

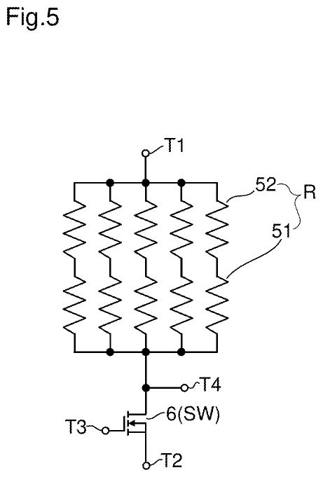

Embodiments of the present invention may incorporate various modifications as follows. FIG. 5 is a modified example of the discharge resistor portion R in the discharge circuit. In the discharge resistor portion R shown in FIG. 5, the connection nodes at each of which one resistor in the first resistor group 51 and one resistor in the second resistor group 52 are connected together in series are not short-circuited together.

In the configuration shown in FIG. 4 or 5, a thermistor such as an NTC (negative temperature coefficient) thermistor can be provided. For example, in FIG. 4 or 5, the thermistor is inserted between one terminal of the first resistor group 51 different from the one at the connection node N side and the node where the drain of the semiconductor chip 6 and the external terminal T4 are connected together.

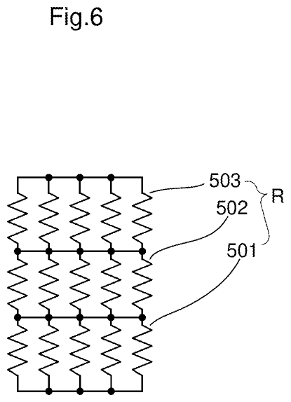

FIG. 6 is another modified example of the discharge resistor portion R. In the configuration shown in FIG. 6, five series circuits each composed of one resistor in the first resistor group 501, one resistor in the second resistor group 502, and one resistor in the third resistor group 503 are connected in parallel. That is, the discharge resister portion R is configured with three series- and five parallel-connected resistors.

Thus, in a case where a discharge circuit is installed, for example, in an EV, the discharge resistor portion R can be given a high withstand voltage. In the example in FIG. 4, where each series circuit has two resistors, if the withstand voltage of one resistor is, for example, 600V, the withstand voltage of the discharge resistor portion R can be 1200V. By contrast, in the example in FIG. 6, where each series circuit has three resistors, even if the withstand voltage of one resistor is lower than the above 600V, for example, 400V, the withstand voltage of the discharge resistor portion R can be 1200V. That is, increasing the number of resistors in each series circuit allows the use of a low-withstand-voltage resistors.

In FIG. 6, the connection nodes at each of which one resistor in the first resistor group 501 and one resistor in the second resistor group 502 are connected together in series are short-circuited together, and so are the connection nodes at each of which one resistor in the second resistor group 502 and one resistor in the third resistor group 503 are connected together in series. However, those connection nodes do not have to be short-circuited.

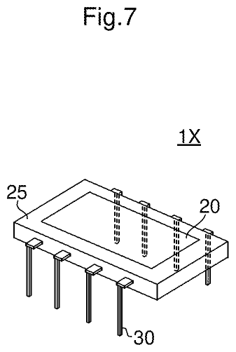

FIG. 7 is a perspective view schematically showing a discharge circuit module 1X according to a modified example. In the configuration shown in FIG. 7, resistors (not illustrated) formed on a ceramic substrate 20 and a semiconductor chip (not illustrated) implemented on the ceramic substrate 20 are sealed with a sealing material 25 (such as resin) into a package. As shown in FIG. 7, the top face of the ceramic substrate 20 is exposed to the outside and a heat sink (not illustrated) can be bonded to this exposed part. External terminals 30 project from the side face of the sealing material 25. As shown in FIG. 7, in case where the number of the external terminals 30 is eight, for example, the four external terminals 30 other than the terminals corresponding to the external terminals T1 to T4 described above are NC terminals (terminals that are not electrically connected inside).

<4. Others>

Although the embodiments of the present disclosure have been described above, various modifications can be made to the embodiments within the scope of the present invention.

<5. Notes>

As described above, for example, a discharge circuit module (1) according to one aspect of what is disclosed herein is a discharge circuit module for discharging a capacitance portion (CX), and includes:
an insulative substrate (40);
a discharge resistor portion (R) having at least one resistor (51, 52) formed on the insulative substrate; and
a semiconductor chip (6) implemented on the insulative substrate as a semiconductor switch and electrically connected to the discharge resistor portion,
wherein
the insulative substrate, the discharge resistor portion, and the semiconductor chip are formed into a package. (A first configuration.)

In the first configuration described above, the insulative substrate may be a ceramic substrate (40). (A second configuration.)

In the second configuration described above, there may be further provided a DCB substrate (4) that includes the ceramic substrate (40) and a wiring portion (41, 42, 43) formed in the ceramic substrate. The resistor (51, 52) and the semiconductor chip (6) may be electrically connected to the wiring portion. (A third configuration.)

In the third configuration described above, there may be further provided a first external terminal (T1, T2) that has a leg portion (T1B, T2B). The wiring portion (43, 41) may make contact with the leg portion. (A fourth configuration.)

In the third or fourth configuration described above, there may be further provided a second external terminal (T3, T4). The wiring portion (41) may be connected to the second external terminal by a bonding wire (W3, W1) or a bonding ribbon. (A fifth configuration.)

In any one of the third to fifth configurations described above, the wiring portion may have:
a first wiring portion (41), a second wiring portion (42), and a third wiring portion (43),
the first, second, and third wiring portions may be arranged in this order in a first direction, and may extend in a second direction orthogonal to the first direction,
a plurality of resistors constituting a first resistor group (51) may be arrayed in the second direction so as to connect together the first and second wiring portions, and
a plurality of resistors constituting a second resistor group (52) may be arrayed in the second direction so as to connect together the second and third wiring portions. (A sixth configuration.)

In any one of the second to sixth configurations described above, there may be further provided a copper plate (2) that is bonded to the ceramic substrate (40). (A seventh configuration.)

In the seventh configuration described above, the ceramic substrate (40) may be bonded to the copper plate (2) via a solder portion (3). (An eighth configuration.)

In any one of the first to eighth configurations described above, there may be further provided a case (7) that stores the insulative substrate (40), the discharge resistor portion (R), and the semiconductor chip (6). (A ninth configuration.)

In the ninth configuration described above, there may be further provided a plate (2) that is bonded to the insulative substrate (40) and that is disposed below the case (7). A fastening hole (7A) provided in the case so as to penetrate in an up-down direction and a through hole (2A) provided in the plate so as to penetrate in the up-down direction may overlap each other as seen from above. (A tenth configuration.)

A discharge system (15) according to another aspect of what is disclosed herein includes the discharge circuit module (1) of any one of the configurations described above and a capacitance portion (CX) connected between supply lines.

### INDUSTRIAL APPLICABILITY

The present disclosure finds applications in, for example, the discharging of an X capacitor.

### REFERENCE SIGNS LIST

1, 1X discharge circuit module
2 copper plate
2A through hole
3 solder portion
4 DCB substrate
6 semiconductor chip
7 resin case
7A fastening hole
8 cover
10 battery
15 discharge system
20 ceramic substrate
25 sealing material
30 external terminal
40 ceramic substrate
41 first wiring portion
42 second wiring portion
43 third wiring terminal
51 first resistor group
52 second resistor group
71 first mount base portion
72 second mount base portion
73 first side portion
74 second side portion
501 first resistor group
502 second resistor group
503 third resistor group
CX capacitance portion
N connection node
R discharge resistor portion
S storage portion
SW semiconductor switch
T1 to T4 external terminal
T1A mount portion
T1B leg portion
T2A mount portion
T2B leg portion
W1 first bonding wire
W2 second bonding wire
W3 third bonding wire

1. A discharge circuit module for discharging a capacitance portion, comprising:
an insulative substrate;
a discharge resistor portion having at least one resistor formed on the insulative substrate; and
a semiconductor chip implemented on the insulative substrate as a semiconductor switch and electrically connected to the discharge resistor portion,
wherein
the insulative substrate, the discharge resistor portion, and the semiconductor chip are formed into a package.

2. The discharge circuit module according to claim 1, wherein the insulative substrate is a ceramic substrate.

3. The discharge circuit module according to claim 2, further comprising:
a DCB substrate including:
the ceramic substrate; and
a wiring portion formed in the ceramic substrate,
wherein the resistor and the semiconductor chip are electrically connected to the wiring portion.

4. The discharge circuit module according to claim 3, further comprising:
a first external terminal having a leg portion,
wherein the wiring portion makes contact with the leg portion.

5. The discharge circuit module according to claim 3, further comprising:
a second external terminal,
wherein the wiring portion is connected to the second external terminal by a bonding wire or a bonding ribbon.

6. The discharge circuit module according to claim 3, wherein
the wiring portion has:
a first wiring portion, a second wiring portion, and a third wiring portion, the first, second, and third wiring portions are arranged in this order in a first direction, and extend in a second direction orthogonal to the first direction,
a plurality of resistors constituting a first resistor group are arrayed in the second direction so as to connect together the first and second wiring portions, and
a plurality of resistors constituting a second resistor group and arrayed in the second direction so as to connect together the second and third wiring portions.

7. The discharge circuit module according to claim 2, further comprising:
a copper plate bonded to the ceramic substrate.

8. The discharge circuit module according to claim 7, wherein the ceramic substrate is bonded to the copper plate via a solder portion.

9. The discharge circuit module according to claim 1, further comprising:
a case storing the insulative substrate, the discharge resistor portion, and the semiconductor chip.

10. The discharge circuit module according to claim 9, further comprising:
a plate bonded to the insulative substrate and disposed below the case,
wherein a fastening hole provided in the case so as to penetrate in an up-down direction and a through hole provided in the plate so as to penetrate in the up-down direction overlap each other as seen from above.

11. A discharge system comprising:
the discharge circuit module according to claim 1; and
a capacitance portion connected between supply lines.
